(19) United States
(12) Patent Application Publication
(10) Pub. No.: US 2025/0279795 A1
(43) Pub. Date: Sep. 4, 2025

(54) SUPPLY VOLTAGE BASED ANALOG PREDISTORTION (APD) CIRCUIT FOR POWER AMPLIFIER

(71) Applicant: Qorvo US, Inc., Greensboro, NC (US)

(72) Inventors: George Maxim, Saratoga, CA (US); Baker Scott, San Jose, CA (US); Nadim Khlat, Cugnaux (FR); Kevin Wesley Kobayashi, Redondo Beach, CA (US)

(21) Appl. No.: 18/858,063

(22) PCT Filed: May 18, 2023
(86) PCT No.: PCT/US2023/022663

§ 371 Date: Oct. 18, 2024

Related U.S. Application Data
(60) Provisional application No. 63/354,279, filed on Jun. 22, 2022.
(60) Provisional application No. 63/385,343, filed on Nov. 29, 2022.

(51) Int. Cl. H04B 1/04; H03F 1/02; H03F 1/32; H03F 3/24

(52) U.S. Cl. CPC H04B 1/0475; H03F 1/0222; H03F 1/3276; H03F 3/245; H03F 2200/471; H04B 2001/0425

(57) ABSTRACT

A supply voltage based analog predistortion (APD) circuit for a power amplifier is disclosed. In an exemplary aspect, the power amplifier is in a front end module (FEM) of a radio frequency (RF) transceiver. An APD circuit operates within an amplifier chain to normalize the distortion profile of the amplifier chain based on a supply voltage. A baseband processor (BBP) performs digital predistortion (DPD) on signals being sent from the BBP to the FEM. As a result of the APD circuit, the DPD may assume a normalized profile for the FEM, allowing for simplification of the DPD despite many possible distortions introduced by the amplifier chain based on the supply voltage.

### PRIORITY APPLICATION

The present application is related to U.S. Provisional Patent Application Ser. 63/385,343 filed on Nov. 29, 2022, and entitled “SUPPLY VOLTAGE BASED ANALOG PREDISTORTION (APD) CIRCUIT FOR POWER AMPLIFIER,” the contents of which is incorporated herein by reference in its entirety.

The present application is related to U.S. Provisional Patent Application Ser. 63/354,279 filed on Jun. 22, 2022, and entitled “FEMs WITH VCC DETECTION-BASED ANALOG-ASSISTED LINEARIZATION FOR DYNAMIC APT,” the contents of which is incorporated herein by reference in its entirety.

### BACKGROUND

### I. Field of the Disclosure

The technology of the disclosure relates generally to providing linear operation for power amplifiers in a transmitter chain.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been increased pressure to find ways to increase communication bandwidth available to supply data to the mobile communication device. This pressure has resulted in a trend to higher frequencies in the evolving cellular standards. These higher frequencies place additional pressure on the power amplifiers within the mobile communication devices to retain linear operation over a wide frequency range. Thus, there is opportunity for innovation in helping the power amplifiers improve linear operation, particularly at high frequencies.

### SUMMARY

Aspects disclosed in the detailed description include a supply voltage based analog predistortion (APD) circuit for a power amplifier. In an exemplary aspect, the power amplifier is in a front end module (FEM) of a radio frequency (RF) transceiver. An APD circuit operates within an amplifier chain to normalize the distortion profile of the amplifier chain based on a supply voltage. A baseband processor (BBP) performs digital predistortion (DPD) on signals being sent from the BBP to the FEM. As a result of the APD circuit, the DPD may assume a normalized profile for the FEM, allowing for simplification of the DPD despite many possible distortions introduced by the amplifier chain based on the supply voltage.

In this regard in one aspect, a transmit chain is disclosed. The transmit chain comprises a power amplifier that imposes distortion on a signal to be transmitted as a function of supply voltage provided to the power amplifier. The transmit chain also comprises an APD circuit coupled to the power amplifier. The APD circuit is configured to normalize the distortion imposed on the signal by the power amplifier.

In another aspect, a method for providing predistortion to a power amplifier is disclosed. The method comprises receiving at a power amplifier a signal to be transmitted. The method also comprises providing APD to the power amplifier based on a supply voltage.

### BRIEF DESCRIPTION OF THE DRAWINGS

FIG. 1 is a block diagram of a power amplifier within a transmitter chain that experiences variable distortion as a function of a supply voltage;

FIG. 2 is a graph of a range of distortions for power amplifiers for different supply voltages across a range of input power (Pin) highlighting the need for predistortion;

FIG. 3 is a graph of a tightened range of distortions for power amplifiers for different mobile terminals versus Pin after analog predistortion (APD) according to the system of FIG. 2;

FIG. 4 is a block diagram of an APD system for a power amplifier showing supply voltage detection and APD corrections;

FIG. 5 is a block diagram of an APD system similar to the APD system of FIG. 4, but with multiple look-up tables (LUTs) to assist in the predistortion;

FIG. 6 is a block diagram of an APD system similar to the APD system of FIG. 4, but with an equation-driven APD controller to avoid use of a LUT;

FIG. 7 is a block diagram showing a varactor being used to assist in applying APD in a transmitter chain in an exemplary aspect of the present disclosure;

FIG. 8 is a block diagram illustrating how APD may be spread across stages within a power amplifier and particularly spread across a hybrid complementary metal oxide semiconductor (CMOS) stage and a bipolar material portion amplifier;

FIG. 9 is a block diagram of an alternate exemplary aspect where all adjustments are calculated in a CMOS portion of a hybrid amplifier but made in both the CMOS portion and the bipolar material portion with two supply voltage detectors;

FIG. 10 is a block diagram of an alternate exemplary aspect, where gain distortion is addressed along with phase distortion;

FIG. 11 is a block diagram of a transmitter chain with additional details about how sampling of the supply voltage may be done to provide measurements for APD;

FIG. 12 illustrates two write signals with sampling triggers identified for a transmitter chain of FIG. 13;

FIG. 13 is a transmitter chain that uses the sampling triggers of FIG. 12;

FIG. 14 is a transmitter chain that uses additional information from a baseband processor (BBP) in evaluating the supply voltage when determining an APD to apply; and

FIG. 15 is a block diagram of a mobile terminal, which may include the predistortion systems of FIGS. 2-14 according to the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include a supply voltage based analog predistortion (APD) circuit for a power amplifier. In an exemplary aspect, the power amplifier is in a front end module (FEM) of a radio frequency (RF) transceiver. An APD circuit operates within an amplifier chain to normalize the distortion profile of the amplifier chain based on a supply voltage. A baseband processor (BBP) performs digital predistortion (DPD) on signals being sent from the BBP to the FEM. As a result of the APD circuit, the DPD may assume a normalized profile for the FEM, allowing for simplification of the DPD despite many possible distortions introduced by the amplifier chain based on the supply voltage.

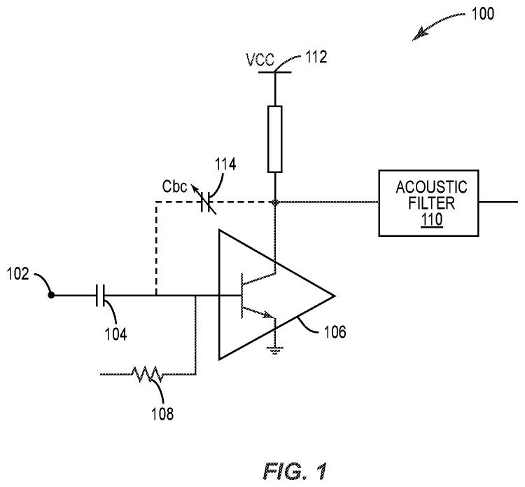

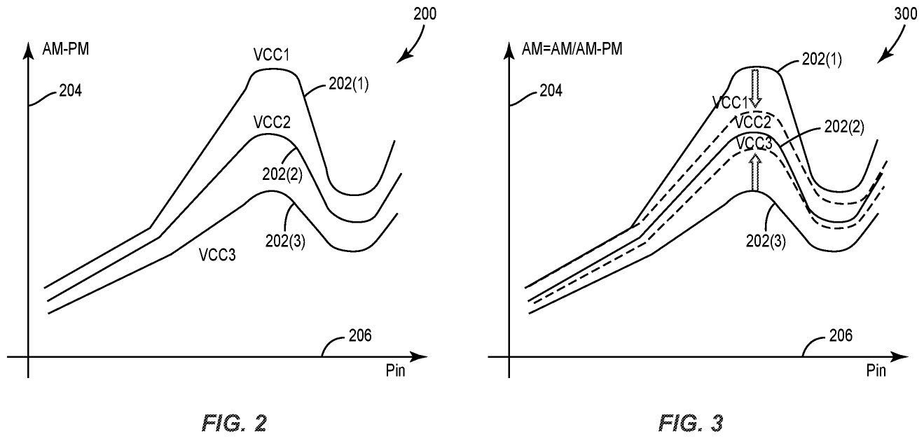

Before addressing exemplary aspects of the present disclosure, a brief overview of some challenges present in conventional devices are explored with reference to FIGS. 1 and 2. A discussion of exemplary aspects of the present disclosure begins below with reference to FIG. 3.

In this regard, FIG. 1 is an exemplary power amplifier stage 100 that may be present in a transmit chain. More specifically, the power amplifier stage 100 may have an input 102 that has a direct current (DC) blocking capacitor 104. Signals arrive through the DC blocking capacitor 104 at an input of a power amplifier 106. The power amplifier 106 may include bipolar transistors (shown) or complementary metal oxide semiconductor (CMOS) transistors (not shown). The power amplifier 106 may also receive a bias signal at the input through a bias resistor 108. An output of the power amplifier 106 may be coupled to an acoustic filter 110 and a supply voltage (VCC) 112. The acoustic filter 110 may have a varying impedance that varies as a function of power levels. A capacitor 114 is effectively formed between a base and a collector of the transistor within the power amplifier 106. The capacitance of this capacitor 114 may vary as a function of the supply voltage 112. Such variation will induce a varying distortion in the output signal. Additional distortion may be induced by impedance fluctuations of the acoustic filter 110. This distortion will primarily be in the phase of the output signal, but some distortion may occur in the amplitude of the output signal.

The distortion will vary not only as a function of the supply voltage, but also as a function of the input power (i.e., the power presented at the input 102) as better illustrated in FIG. 2, where graph 200 shows the phase distortion of three different supply voltages (VCC1-VCC3) in three curves 202(1)-202(3). Specifically, the y-axis 204 is the distortion and the x-axis 206 is the input power (Pin) at the input 102.

In general, the distortion induced by the variation in the power has been addressed by providing digital predistortion (DPD) in a baseband processor (BBP). When the supply voltage is constant, a relatively small number of DPD coefficients may be needed. However, when the supply voltage is constant, it must be set high enough to accommodate any power peaks, which results in inefficiencies at lower power levels. This inefficiency led to the introduction of fast average power tracking (APT) circuits, which may change supply voltages in each slot and/or even for each symbol. However, each supply voltage will necessitate its own set of DPD coefficients. As the granularity of the supply voltages increases, the burden in terms of memory on the BBP increases. This burden translates to increased cost, increased space consumed, and potentially adds to latency.

Exemplary aspects of the present disclosure help alleviate the burden on the BBP by adding in APD circuitry to the power amplifier stage in a transmitter that normalizes the distortion caused by varying supply voltages. When the distortion profile caused by the varying supply voltages is normalized, the BBP may provide DPD that matches that normalized profile, obviating the need for numerous sets of DPD coefficients in the BBP as better seen in graph 300 of FIG. 3. In particular, graph 300 shows curves 202(1) and 202(3) being distorted by APD circuitry to be closer to curve 202(2) allowing the BBP to have DPD coefficients for just the general shape of curve 202(2).

While the distortion is primarily phase distortion, both phase and gain distortion may be corrected with the APD circuitry of the present disclosure. Further, the APD circuitry of the present disclosure may be spread across multiple stages (e.g., a driver stage and an output stage) or across technologies (e.g., a bipolar transistor portion and CMOS transistor portion). The APD circuitry may adjust bias signals or otherwise modulate operation with varactors or the like. Likewise, knowledge of the supply voltage may be acquired through various sensors, signals from the BBP, and/or at certain timing intervals. All of these aspects are discussed in greater detail below.

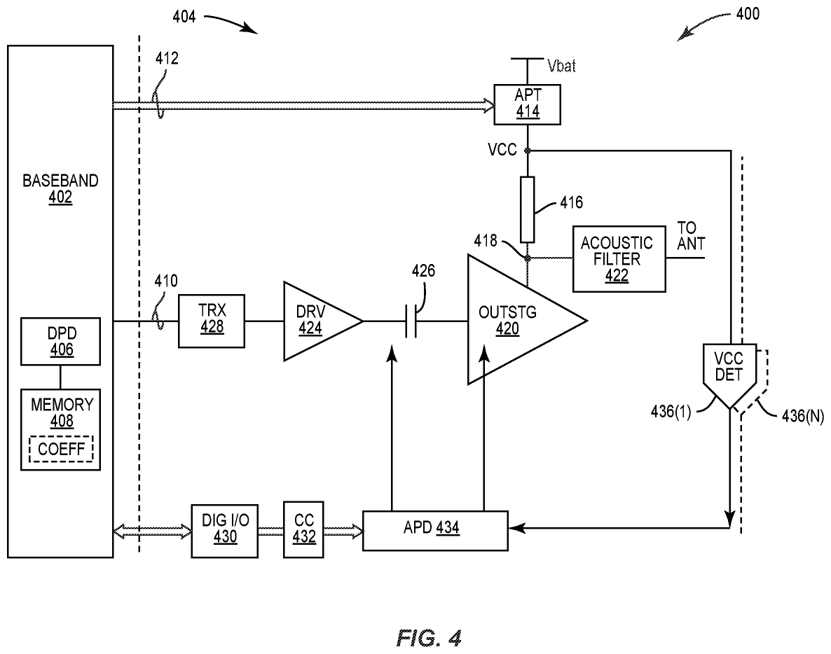

In this regard, FIG. 4 illustrates a transmit chain 400 that includes a BBP 402 and an amplifier chain 404. The BBP 402 includes a DPD circuit 406 with a memory 408 associated therewith that stores DPD coefficients. The memory 408 may be relatively small because a small set of DPD coefficients may be used by the BBP 402. The BBP 402 generates a signal 410 to be transmitted as well as a control signal 412 for a power tracking circuit 414 in the amplifier chain 404. In an exemplary aspect, the power tracking circuit 414 may be an APT circuit, and may be referred to as a fast APT, a dynamic APT, a symbol tracking circuit, or even a sub-symbol tracking circuit. The power tracking circuit 414 takes a known voltage level such as Vbat and converts this voltage level to a desired supply voltage (VCC) based on the control signal 412. The supply voltage is provided through an impedance 416 to an output 418 of a power amplifier 420. The output 418 is coupled to an antenna (not shown) through a filter 422, which may be an acoustic filter.

The amplifier chain 404 may have multiple amplifier stages including the power amplifier 420 (which may be an output stage amplifier) and a driver stage amplifier 424. A blocking capacitor 426 may separate the amplifiers 420, 424. Additional transmit circuitry (e.g., upconversion circuitry, switches, filters, or the like) 428 may also be present in the amplifier chain 404. Still further, the amplifier chain 404 may include a digital input/output (I/O) 430 that receives additional signals or information from the BBP 402 such as mode information, channel information, or the like. The digital I/O 430 may also be associated with a control circuit 432. Alternatively, the control circuit 432 may be incorporated into the digital I/O 430.

As still another option, the control circuit 432 may be incorporated into an APD circuit 434. The APD circuit 434 receives signals from one or more supply voltage detectors 436(1)-436(N) and generates control signals that may modify the operation of one more of the amplifiers 420, 424 to apply distortion in such a manner that normalizes the overall distortion of the amplifier chain 404 to one of a few (e.g., one) predetermined distortion curves.

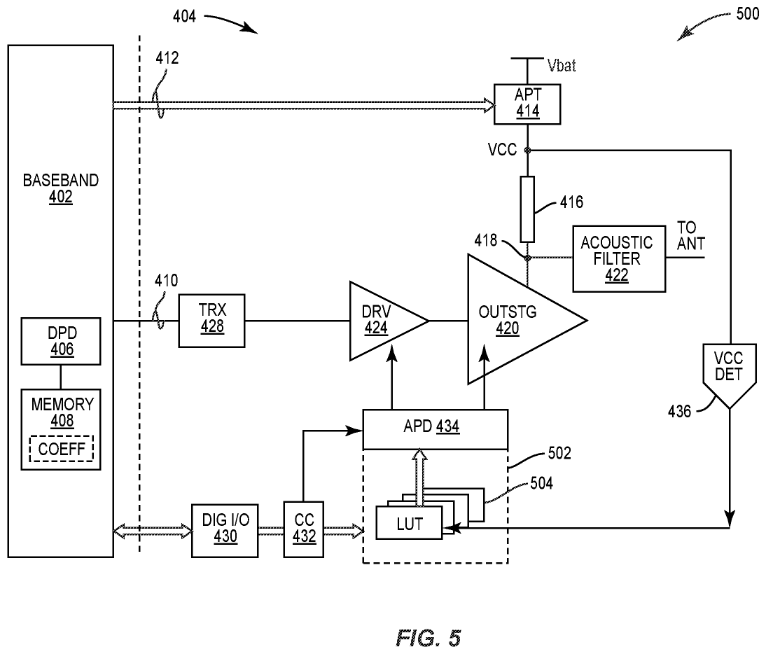

FIG. 5 shows a transmit chain 500 which highlights one way in which the APD circuit 434 may determine what control signals to generate. Specifically, the APD circuit 434 may have an associated memory 502 that stores a look-up table (LUT) 504 having multiple pages thereon corresponding to power levels and detected supply voltages. Based on these inputs, and optionally inputs from the control circuit 432, appropriate entries in the LUT 504 are selected and used.

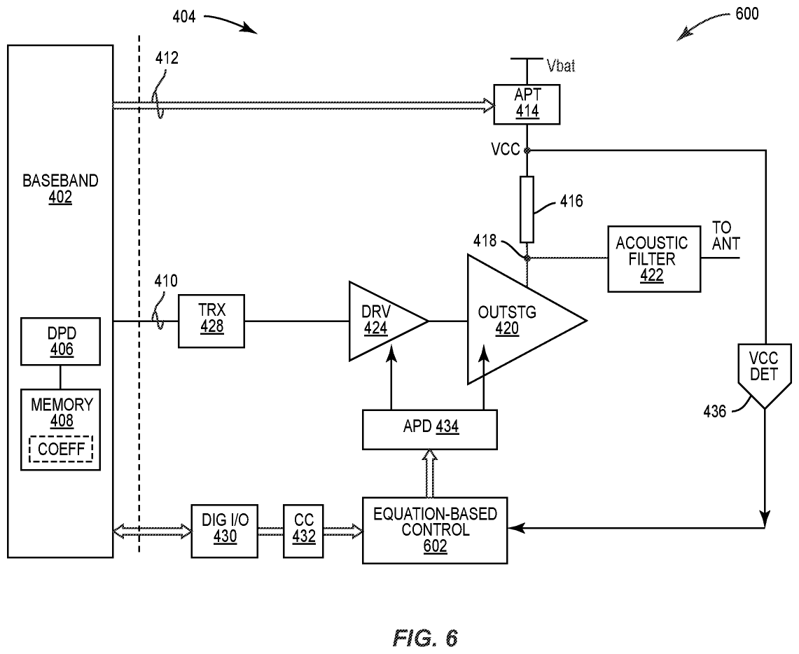

Alternatively, as illustrated in FIG. 6, a transmit chain 600 may have an APD circuit 434 that includes an equation-based control circuit 602 that calculates appropriate signals for each detected supply voltage. This approach may avoid a large LUT but may require additional computation circuitry.

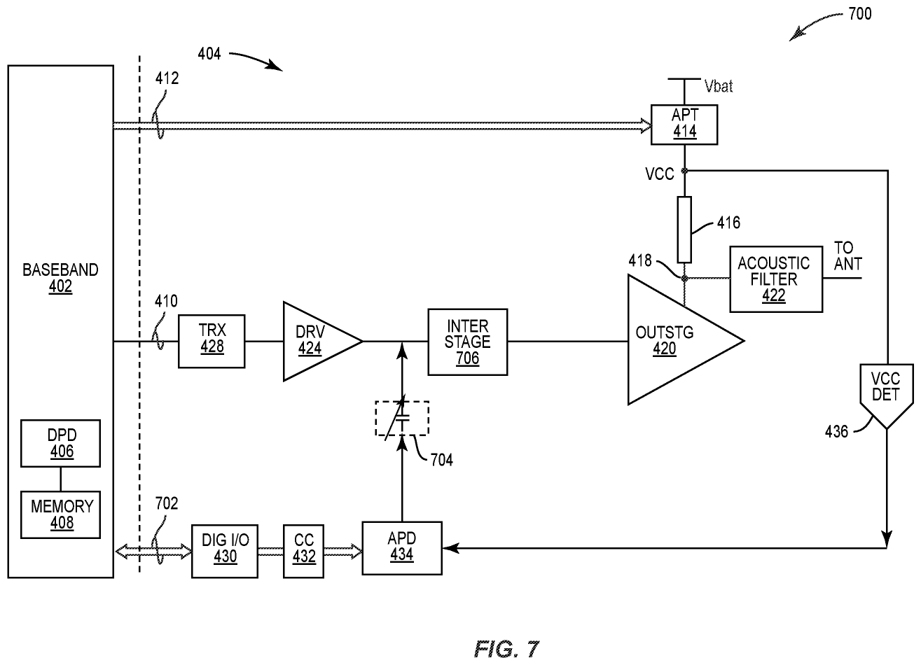

While the transmit chain 400 relies on the supply voltage detectors 436(1)-436(N) and transmit chains 500, 600 rely on a supply voltage detector 436, the amplifier chain 404 of a transmit chain 700 in FIG. 7 may also receive supply voltage information from the BBP in a signal 702 passed through the digital I/O 430. In some aspects, the information in the signal 702 may match the information in the control signal 412. Further, FIG. 7 shows that the signals generated by the APD circuit 434 may adjust a varactor 704 that may operate with interstage circuitry 706 to provide desired APD. Note the varactor 704 may be a bank of parallel capacitors with selected ones switched in and out to provide a desired capacitance or other variable capacitor structure.

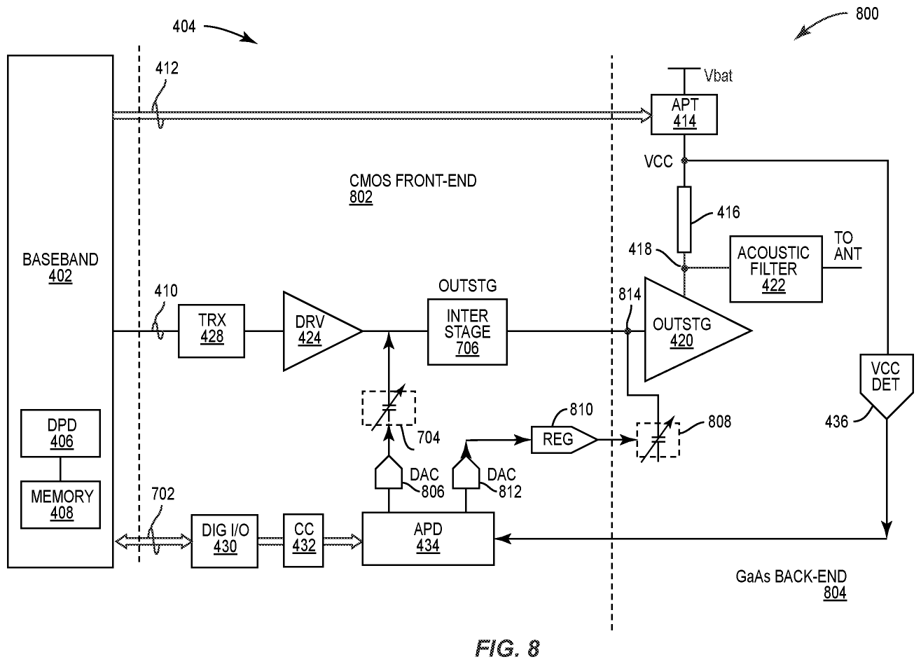

More detail about a possible implementation is provided in FIG. 8 where a transmit chain 800 is implemented across different technologies. Specifically, a front-end portion 802 of the amplifier chain 404 is implemented in CMOS and may operate in the digital domain. A back-end portion 804 may be implemented in a bipolar material (e.g., gallium arsenide (GaAs)) and may operate in the analog domain. The APD circuit 434 may use a digital-to-analog converter (DAC) 806 to turn a digital signal into an analog signal to control the varactor 704. Likewise, a varactor 808 may be implemented in the back-end portion 804. The varactor 808 may be controlled by a regulator 810, which in turn receives an analog signal from a DAC 812 coupled to the APD circuit 434. The varactor 808 may couple to a node 814 at an input of the power amplifier 420 (e.g., at a base of a bipolar transistor within the power amplifier 420).

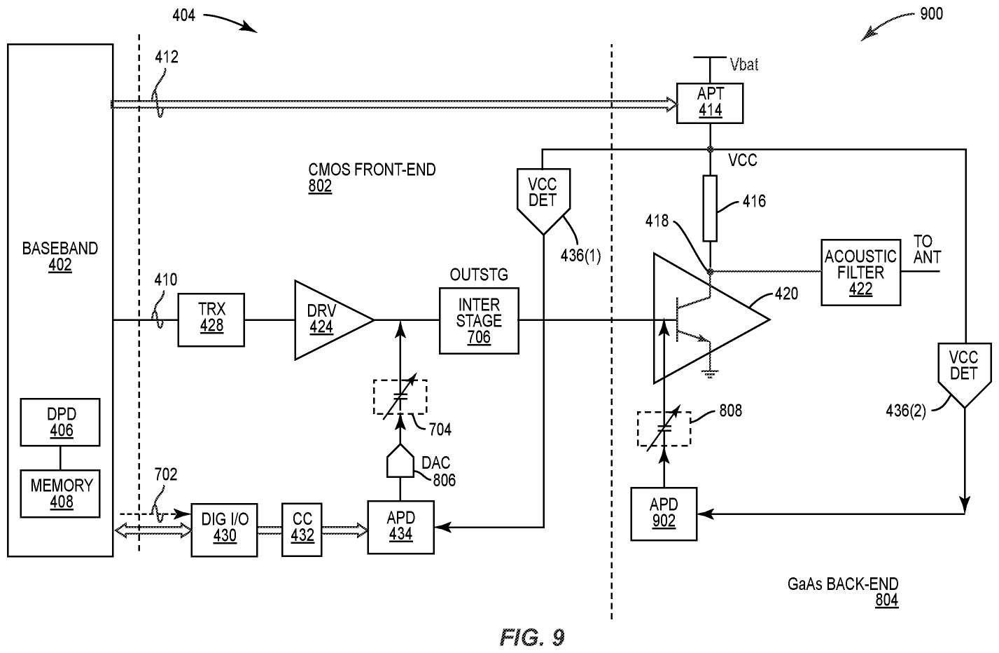

As an alternative, the supply voltage detectors 436(1)-436(N) may be split across technologies as illustrated by transmit chain 900 in FIG. 9. More specifically, the supply voltage detector 436(1) may be implemented in CMOS and provide a digital signal to the APD circuit 434, which controls the varactor 704 as previously described. Additionally, the supply voltage detector 436(2) may be implemented in bipolar technology and use an APD circuit 902 to control the varactor 808.

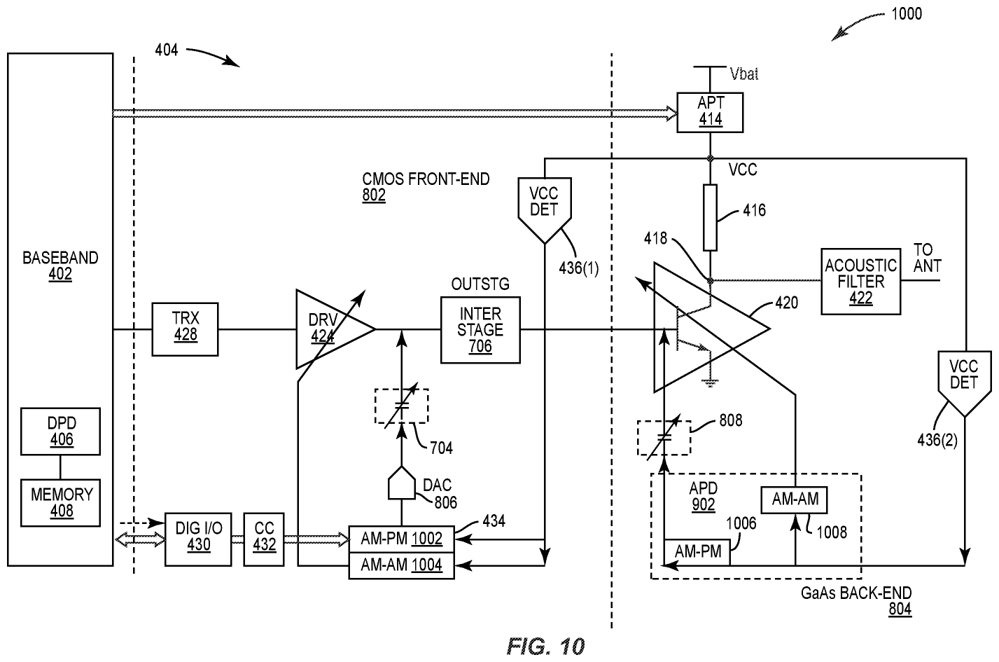

The above discussion has not specified what types of distortion are corrected. It should be appreciated that the APD of the present disclosure may correct phase distortion (i.e., so called amplitude modulation (AM)-to-phase modulation (PM) (AM-PM) distortion) or gain distortion (i.e., so called AM-to-AM (AM-AM) distortion) or both. FIG. 10 illustrates a transmit chain 1000 that explicitly shows this latter possibility. Specifically, the APD circuit 434 may include an AM-PM circuit 1002 that controls the varactor 704 through the DAC 806. The APD circuit 434 may further include an AM-AM circuit 1004 that controls a gain of the driver amplifier 424. Likewise, the APD circuit 902 may include an AM-PM circuit 1006 that controls the varactor 808 and an AM-AM circuit 1008 that controls the gain of the power amplifier 420. While both APD circuits 434, 902 are shown with both AM-PM and AM-AM circuits, it should be appreciated that one APD circuit 434, 902 may correct phase and the other APD circuit correct gain or one APD circuit 434, 902 may correct both phase and gain while the other only corrects phase (or only corrects gain). Likewise, while shown as two separate APD circuits 434, 902, it should be appreciated that in some aspects, a single APD circuit implemented in just CMOS or just bipolar technology may be present. Likewise, the APD circuits 434, 902 may use a LUT or equations as needed or desired.

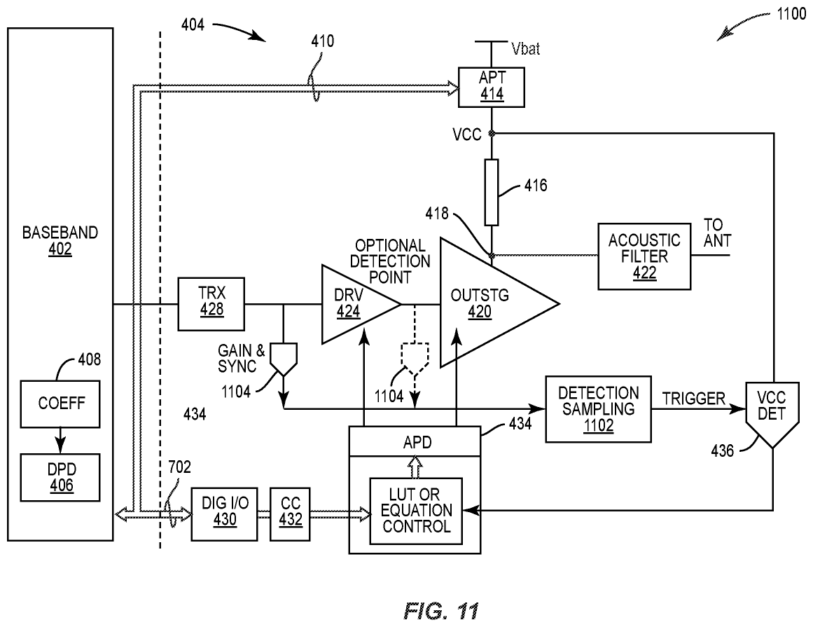

The present disclosure has been silent so far on how the supply voltage detectors 436(1)-436(N) work. While the supply voltage detectors 436(1)-436(N) may be continuous, it is more likely that the supply voltage detectors 436(1)-436(N) will sample periodically such as once per slot or once per symbol, depending, potentially, on how frequently the supply voltage is changed (i.e., how quickly the power tracking circuit 414 changes VCC may dictate how frequently VCC needs to be sampled. FIG. 11 shows one possibility for a transmit chain 1100 that has a sampling circuit 1102 that uses information from an edge detector 1104 and a delay circuit (not shown) to trigger the supply voltage detector 436. While shown before the driver amplifier 424, the edge detector 1104 may be positioned between the amplifiers 420, 424.

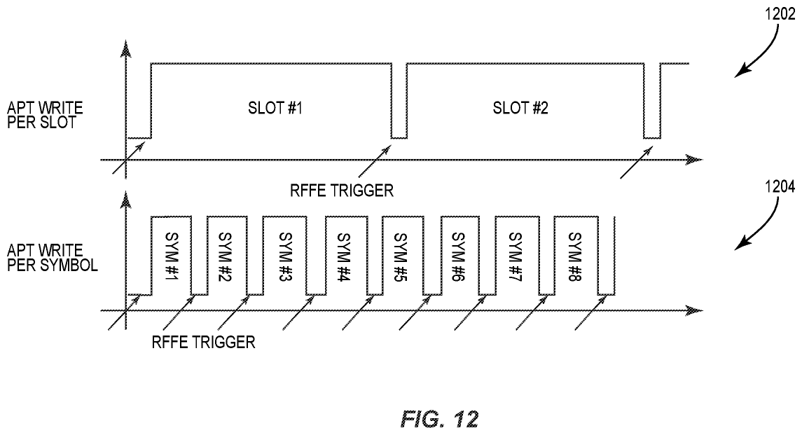

FIG. 12 shows signals 1202 and 1204 which have per-slot and per-symbol trigger edges, respectively. The signals 1202, 1204 would be the signal generated by the power tracking circuit 414 (also sometimes referred to as a power management integrated circuit (PMIC)), and these edges may be what is detected by the supply voltage detector 436.

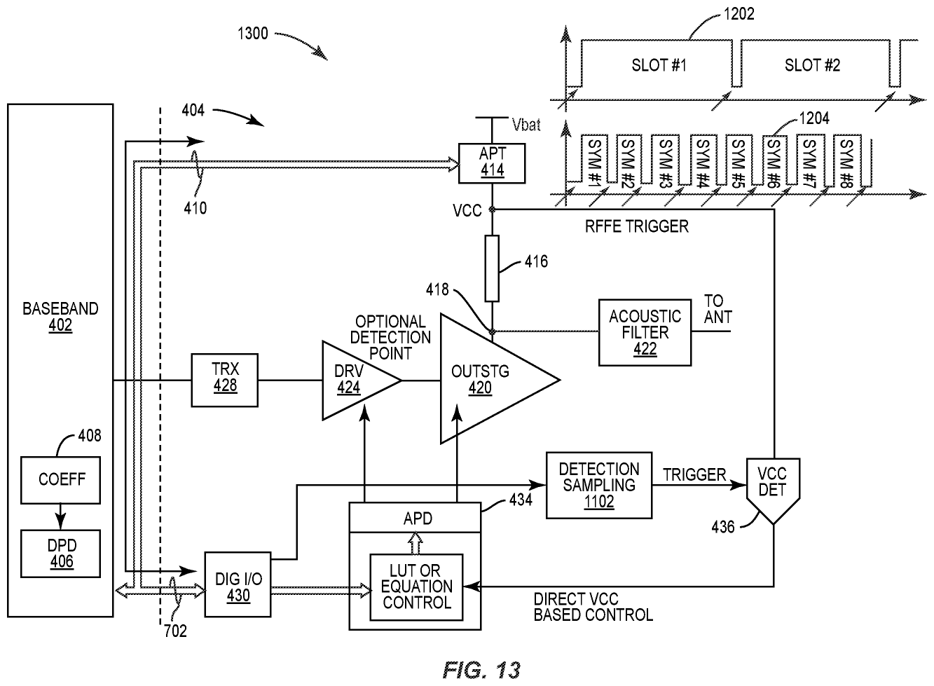

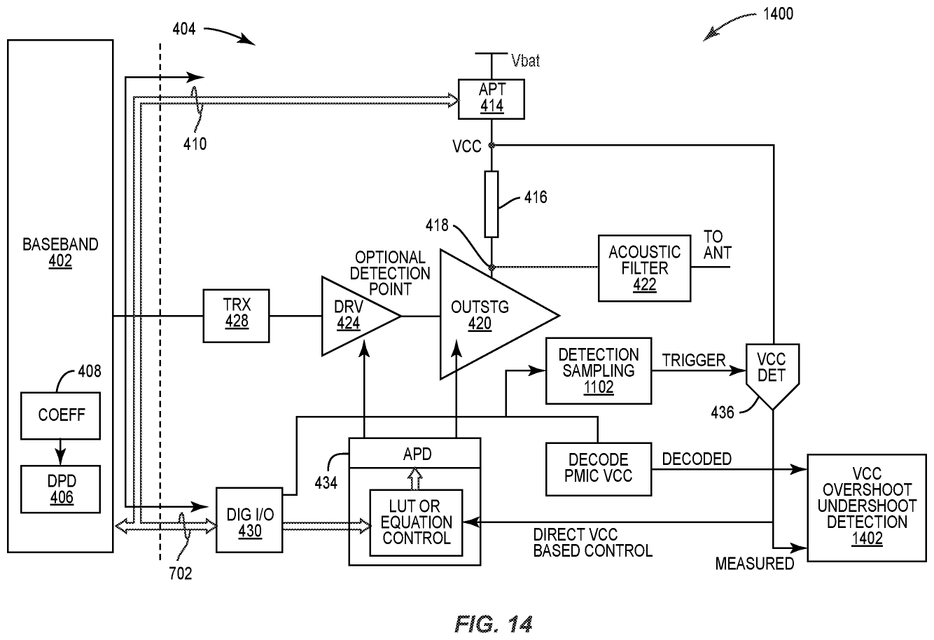

When the signals 1202, 1204 are combined with the transmit chain 1100, the result is shown in a transmit chain 1300 in FIG. 13. Note that the trigger may also be provided directly from the BBP 402.

Note that the information in the signal 702 may also be compared to information from the supply voltage detector 436 to see if the power tracking circuit 414 is undershooting or overshooting relative to the instruction from the BBP 402 as illustrated in FIG. 14 where a transmit chain 1400 includes a comparison circuit 1402 that compares a decoded target supply voltage to a measured supply voltage.

Note that various aspects of the present disclosure may be mixed and matched because many of the elements are not mutually exclusive. For example, the supply voltage detectors 436(1)-436(N) may all be CMOS detectors or all bipolar detectors. Other variations not illustrated or specifically set forth still fall within the scope of the present disclosure.

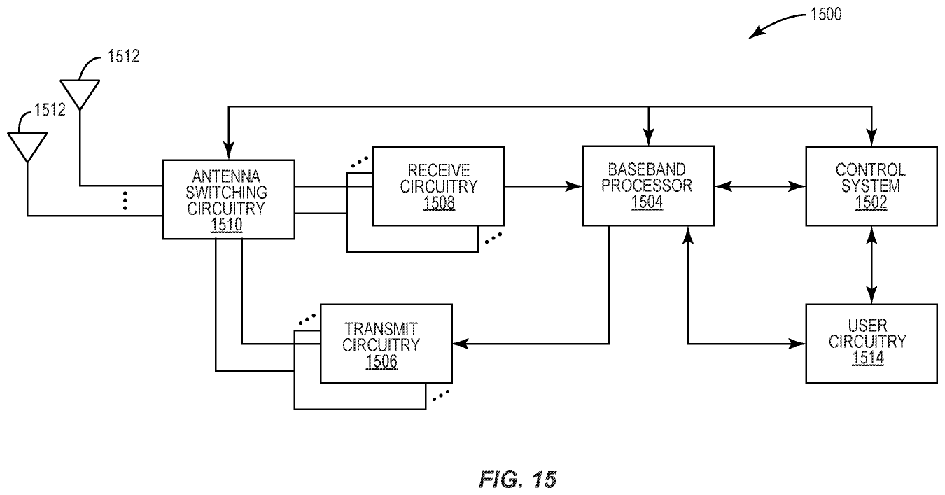

With reference to FIG. 15, the concepts described above may be implemented in various types of user elements 1500, such as mobile terminals, smart watches, tablets, computers, navigation devices, access points, and like wireless communication devices that support wireless communications, such as cellular, wireless local area network (WLAN), Bluetooth, and near field communications. The user elements 1500 will generally include a control system 1502, a BBP 1504, transmit circuitry 1506 (which may include any of the transmit chains 400, 500, 600, 700, 800, 900, 1000, 1100, 1300, or 1400 described above), receive circuitry 1508, antenna switching circuitry 1510, multiple antennas 1512, and user interface circuitry 1514. In a non-limiting example, the control system 1502 can be a field-programmable gate array (FPGA) or an application-specific integrated circuit (ASIC), as an example. In this regard, the control system 1502 can include at least a microprocessor(s), an embedded memory circuit(s), and a communication bus interface(s). The receive circuitry 1508 receives radio frequency (RF) signals via the antennas 1512 and through the antenna switching circuitry 1510 from one or more base stations. A low noise amplifier and a filter of the receive circuitry 1508 cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADCs).

The BBP 1504 processes the digitized received signal to extract the information or data bits conveyed in the received signal. This processing typically comprises demodulation, decoding, and error correction operations, as will be discussed on greater detail below. The BBP 1504 is generally implemented in one or more digital signal processors (DSPs) and ASICs.

For transmission, the BBP 1504 receives digitized data, which may represent voice, data, or control information, from the control system 1502, which it encodes for transmission. The encoded data is output to the transmit circuitry 1506, where a DAC converts the digitally-encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 1512 through the antenna switching circuitry 1510. The multiple antennas 1512 and the replicated transmit and receive circuitries 1506, 1508 may provide spatial diversity. Modulation and processing details will be understood by those skilled in the art.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

1. A transmit chain comprising:
a power amplifier that imposes amplifier distortion on a digitally predistorted signal to be transmitted, wherein the amplifier distortion is a function of supply voltage provided to the power amplifier; and
an analog predistortion (APD) circuit coupled to the power amplifier, the APD circuit configured to normalize the amplifier distortion imposed on the digitally predistorted signal by the power amplifier such that digital predistortion (DPD) applied to create the digitally predistorted signal may be achieved with coefficients corresponding to normalized amplifier distortion.

2. The transmit chain of claim 1, wherein the APD circuit comprises a varactor coupled to the power amplifier.

3. The transmit chain of claim 1, further comprising a supply voltage detector coupled to an output of the power amplifier.

4. The transmit chain of claim 1, further comprising a second power amplifier coupled in series to the power amplifier.

5. The transmit chain of claim 4, wherein the APD circuit is further configured to predistort the second power amplifier to offset variations as a function of the supply voltage.

6. The transmit chain of claim 1, further comprising a power tracking circuit configured to set the supply voltage responsive to a control signal from a baseband processor (BBP).

7. The transmit chain of claim 6, wherein the power tracking circuit is configured to set the supply voltage on a per-slot basis.

8. The transmit chain of claim 6, wherein the power tracking circuit is configured to set the supply voltage on a per-symbol basis.

9. The transmit chain of claim 3, wherein the supply voltage detector is configured to sample a voltage level on a per-slot basis.

10. The transmit chain of claim 3, wherein the supply voltage detector is configured to sample a voltage level on a per-symbol basis.

11. The transmit chain of claim 1, further comprising a baseband processor (BBP) coupled to the power amplifier and configured to provide the signal to be transmitted.

12. The transmit chain of claim 11, wherein the BBP comprises a digital predistortion (DPD) circuit configured to provide the digitally predistorted signal that offsets a normalized distortion profile of the power amplifier.

13. The transmit chain of claim 1, wherein the power amplifier comprises a bipolar transistor.

14. The transmit chain of claim 1, wherein the APD circuit is configured to provide phase distortion APD.

15. The transmit chain of claim 1, wherein the APD circuit is configured to provide gain distortion APD.

16. The transmit chain of claim 3, wherein the supply voltage detector is configured to detect voltage levels continuously.

17. A method for providing predistortion to a power amplifier, comprising:
receiving at a power amplifier a digitally predistorted signal to be transmitted; and
providing analog predistortion (APD) to the power amplifier based on a supply voltage, wherein the APD normalizes the digitally predistorted signal such that digital predistortion, DPD, applied to create the digitally predistorted signal may be achieved with coefficients corresponding to normalized amplifier distortion.

18. The method of claim 17, further comprising providing the DPD on the signal to be transmitted at a baseband processor (BBP) prior to receiving at the power amplifier.

19. The method of claim 17, wherein providing the APD comprises providing phase distortion to the signal to be transmitted.

20. The method of claim 17, wherein providing the APD comprises providing gain distortion to the signal to be transmitted.
